(19) United States
(12) Patent Application Publication
(10) Pub. No.: US 2021/0281234 A1
(43) Pub. Date: Sep. 9, 2021

(54) HYBRID THREE DIMENSIONAL INDUCTOR

(71) Applicant: QUALCOMM Incorporated, San Diego, CA (US)

(72) Inventors: Jonghae KIM, San Diego, CA (US); Milind SHAH, San Diego, CA (US); Periannan CHIDAMBARAM, San Diego, CA (US)

(21) Appl. No.: 16/812,294

(22) Filed: Mar. 7, 2020

(51) Int. Cl. H03H 7/01; H01L 49/02; H01F 17/00; H01L 27/06

(52) U.S. Cl. CPC H03H 7/1741; H01L 28/10; H01L 28/60; H03H 7/0153; H01L 27/0688; H01F 17/0006

(57) ABSTRACT

An improved filter for high frequency, such as 5G wireless communication, may include inductor-Q improvement and reduced die-size with a hybrid 3D-inductor integration. In some examples, the inductors may be formed using an IPD and a fan-out package. For instance, a first multilayer substrate comprises a plurality of metal insulator metal (MIM) capacitors formed using various layers (e.g., M1 and M2) and a first portion of the 3D inductors, and a second multilayer substrate comprises at least a second portion of the 3D inductors. The 3D inductors may be electrically coupled to the MIM capacitors to form at least one filter network.

### FIELD OF DISCLOSURE

This disclosure relates generally to inductors, and more specifically, but not exclusively, to three dimensional (3D) inductors.

### BACKGROUND

As wireless communication systems become more prevalent, there is a need for increasing the performance and capacity of existing wireless communication networks. The next generation standard, 5G, is the fifth generation wireless technology for digital cellular networks. As with previous standards, the covered areas are divided into regions called “cells”, serviced by individual antennas. Virtually every major telecommunication service provider in the developed world is deploying antennas or intends to deploy them soon. The frequency spectrum of 5G is divided into millimeter waves, mid-band and low-band. Low-band uses a similar frequency range as the predecessor, 4G. The 5G millimeter wave is the fastest, with actual speeds often being 1-2 Gb/s for the downlink. Frequencies are above 24 GHz reaching up to 72 GHz which is above extremely high frequency's lower boundary. The reach is short, so more cells are required. Millimeter waves have difficulty traversing many walls and windows, so indoor coverage is limited. The 5G mid-band is the most widely deployed, in over 20 networks. Speeds in a 100 MHz wide band are usually 100-400 Mb/s for the downlink. Frequencies deployed are from 2.4 GHz to 4.2 GHz. However, as the frequencies being used increase, the filter designs for the wireless communication devices must also change to adapt to changing frequency bands.

Conventional filter designs, including integrated passive device (IPD) based filters, rely on planar (2D) inductors formed in the die. However, with the increased number of frequencies and increased bandwidth in 5G systems, the conventional inductor/filter designs are not satisfactory in either performance or size. For example, the prior 4G systems typically had a bandwidth of less than 100 MHz, whereas filter performance for 5G systems will have to accommodate increased bandwidths of 400 MHz or greater.

Accordingly, there is a need for systems, apparatus, and methods that overcome the deficiencies of conventional approaches including the methods, system and apparatus provided hereby that improve the filter performance through inductor-Q improvement and reduce the die-size.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

In one aspect, a filter package comprises: a first multilayer substrate, the first multilayer substrate comprises a plurality of metal insulator metal (MIM) capacitors and a first portion of a plurality of three dimensional (3D) inductors; and a second substrate, the second substrate comprises a second portion of the plurality of 3D inductors wherein the plurality of 3D inductors are electrically coupled to the plurality of MIM capacitors to form a filter network.

In another aspect, a filter package comprises: a first multilayer substrate, the first multilayer substrate comprises a plurality of metal insulator metal (MIM) capacitors and a first portion of means for storing electrical energy; and a second substrate, the second substrate comprises a second portion of the means for storing electrical energy wherein the means for storing electrical energy are electrically coupled to the plurality of MIM capacitors to form a filter network.

In still another aspect, a method for manufacturing a filter package comprises: forming a first multilayer substrate, the first multilayer substrate comprises a plurality of metal insulator metal (MIM) capacitors and a first portion of a plurality of three dimensional (3D) inductors; forming a second substrate, the second substrate comprises a second portion of the plurality of 3D inductors; and electrically coupling the plurality of 3D inductors to the plurality of MIM capacitors to form a filter network.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure, and in which:

FIG. 1 illustrates a plan view of an exemplary filter package in accordance with some examples of the disclosure;

FIG. 2 illustrates a side view of an exemplary filter package in accordance with some examples of the disclosure;

FIG. 3 illustrates a side view of an exemplary filter package in accordance with some examples of the disclosure;

FIG. 4 illustrates a side view of an exemplary 3D inductor in accordance with some examples of the disclosure;

FIGS. 5A-C illustrate an exemplary 3D inductor in accordance with some examples of the disclosure;

FIG. 6 illustrates an exemplary partial method in accordance with some examples of the disclosure;

FIG. 7 illustrates an exemplary mobile device in accordance with some examples of the disclosure; and

FIG. 8 illustrates various electronic devices that may be integrated with any of the aforementioned methods, devices, semiconductor devices, integrated circuits, die, interposers, packages, or package-on-packages (PoPs) in accordance with some examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

The exemplary methods, apparatus, and systems disclosed herein mitigate shortcomings of the conventional methods, apparatus, and systems, as well as other previously unidentified needs. Examples herein may include a hybrid 3D-inductor comprising both integrated passive device (IPD) layers and redistribution layers (RDLs) in a fan-out-package (FO PKG) that allows for improved 5G filters' insertion-loss and reduces die size. Additionally, the inductor-Q is improved through a 3D solenoid inductor-structure by expanding the coil's aperture with a hybrid-technique (IPD and FO PKG). In various aspects, conventional planar inductors are replaced by 3D inductors that have a higher Q, which results in an increased inductance (L) to resistance (R) ratio for a given frequency.

In some examples, the inductors are formed in combination using an IPD and a fan-out package. For example, a first multilayer substrate (IPD) comprises a plurality of metal insulator metal (MIM) capacitors formed using various layers (e.g., M1 and M2) and a first portion of the 3D inductors and a second multilayer substrate comprises at least a second portion of the 3D inductors. In another example, the hybrid 3D inductor may be formed as part of a filter package. The filter package may comprise a first multilayer substrate with MIM capacitors and at least a first portion of the 3D inductors formed on the various metal layers, a second substrate with a second portion of the 3D inductors where the two portions combine to form the windings of the 3D inductor(s). The first multilayer substrate and the second substrate are electrically coupled via a copper pillar/copper stud which can form part of the 3D inductor (e.g., vertical portion of winding) that also allow a vertical extension to the filter package while reducing the width (die size). Additionally, copper traces of a redistribution layer in the second substrate may be used to form part of the 3D inductor (e.g., horizontal bottom portions of winding). The first multilayer substrate may have the first portion of the plurality of 3D inductors formed using metal layers closest to the second substrate (M3 and M4), and the MIM capacitors may be formed using metal layers (e.g., M1 and M2) further from the second substrate. In some examples, the first multilayer substrate is an integrated passive device and the second substrate is a fan-out package. The 3D inductors may be electrically coupled to the MIM capacitors to form at least one filter network. Additionally, it will be appreciated that the first multilayer substrate (IPD) may include at least one planar inductor. Accordingly, not all inductors have to be configured as 3D inductors.

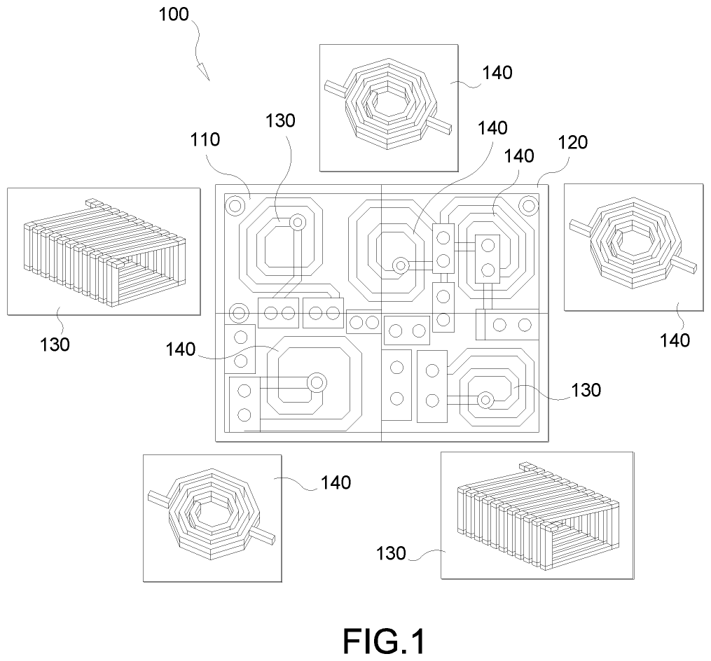

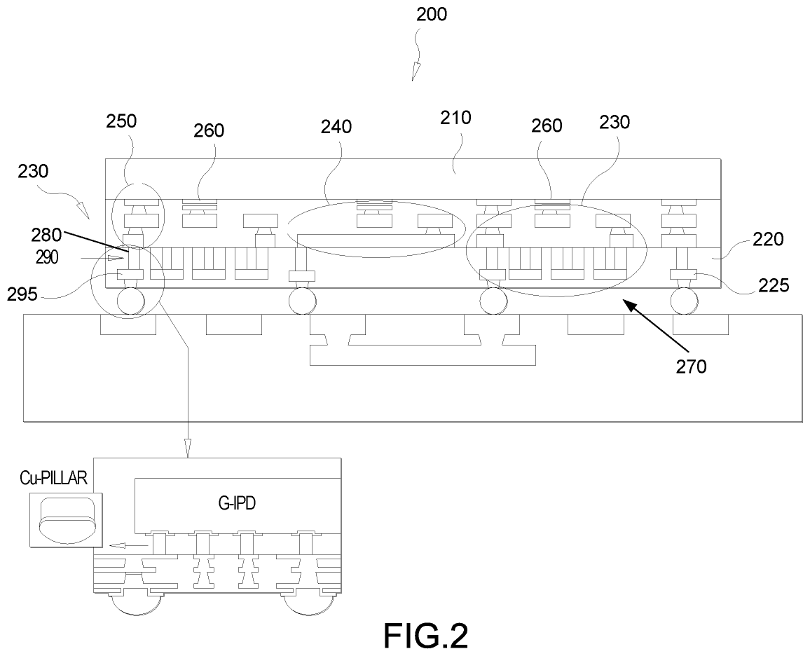

FIG. 1 illustrates a plan view of an exemplary filter package in accordance with some examples of the disclosure. As shown in FIG. 1, a filter package 100 may include a first multilayer substrate 110 with a first portion of a plurality of three dimensional (3D) inductors 130, and a second substrate 120 with a second portion of the plurality of 3D inductors 130 wherein the plurality of 3D inductors 130 are electrically coupled to a plurality of MIM capacitors (see FIG. 2) integrated into the first multilayer substrate 110 to form a filter network. As shown in FIG. 1, the filter package 100 may also include one or more planar inductors 140. The planar inductors 140 have a low Q rating while the 3D inductors 130 have a high Q rating. Since the inductor=

$$\frac{ω \cdot L}{R} ,$$

inductor-Q is improved through the 3D solenoid inductor 130 structure by expanding the coil's aperture with a hybrid-technique (i.e., IPD and FO PKG). Replacing the conventional planar inductors with 3D inductors that have a higher Q results in an increased inductance (L) to resistance (R) ratio for a given frequency. However, not all planar inductors need be replaced, especially when the total circuit Q is better suited by using one or more lower Q planar inductors and/or when the second substrate 120 below the planned inductor location does not have the structure to support a 3D inductor

FIG. 2 illustrates a side view of an exemplary filter package in accordance with some examples of the disclosure. As shown in FIG. 2, a filter package 200 (e.g., filter package 100) may include a first multilayer substrate 210 with a first portion 250 of a plurality of 3D inductors 230 and a plurality of MIM capacitors 260, and a second substrate 220 with a second portion 270 of the plurality of 3D inductors 230 wherein the plurality of 3D inductors 230 are electrically coupled to a plurality of MIM capacitors 260 to form a filter network. As shown in FIG. 2, the first multilayer substrate 210 and the second substrate 220 are electrically coupled via a plurality of copper pillars (or columns or studs) 280 in the second substrate 220 and the plurality of copper pillars 280 form a third portion 290 of the plurality of 3D inductors 230. The copper pillars 280 may be any suitable height, such as less than 40 nm. Also shown in FIG. 2, a redistribution layer 225 in the second substrate 220 forms a fourth portion 295 of the plurality of 3D inductors 230. The third portion 290 and the fourth portion 295 may be considered as part of the second portion 270. As shown, the first portion 250 of the plurality of 3D inductors 230 comprises a first plurality of metal layers of the first multilayer substrate 210 closest to the second substrate 220 and the plurality of MIM capacitors 260 comprises a second plurality of metal layers further away from the second substrate 220 than the first plurality of metal layers. The filter package 200 may also include one or more planar inductors 240. It should be understood that the first multilayer substrate 210 may be an integrated passive device (IPD) and the second substrate 220 may be a fan-out package.

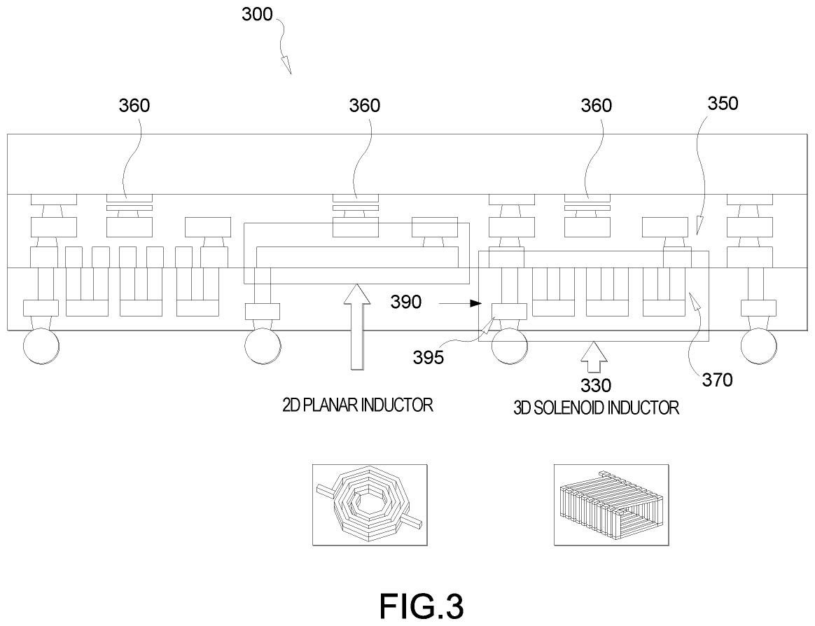

FIG. 3 illustrates a side view of an exemplary filter package in accordance with some examples of the disclosure. As shown in FIG. 3, a filter package 300 may include a first portion 350 of a plurality of 3D inductors 330, a plurality of MIM capacitors 360, a second portion 370 of the plurality of 3D inductors 330, a third portion 390 of the plurality of 3D inductors 330, and a fourth portion 395 of the plurality of 3D inductors 330. The third portion 390 and the fourth portion 395 may be considered as part of the second portion 370.

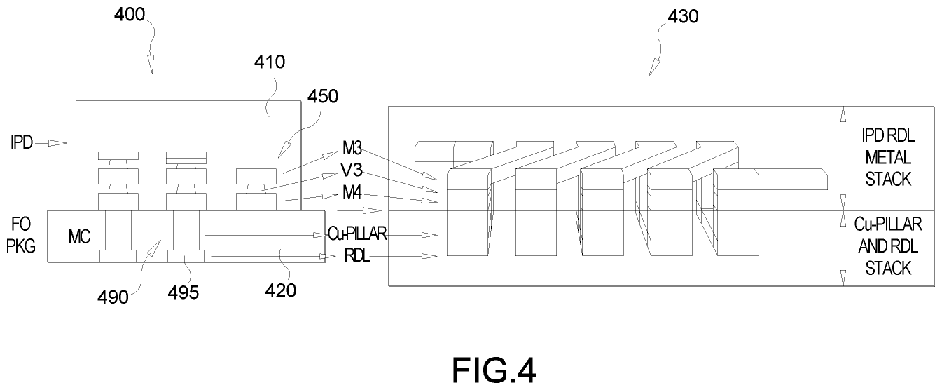

FIG. 4 illustrates a side view of an exemplary 3D inductor in accordance with some examples of the disclosure. As shown in FIG. 4, a filter package 400 may include a first multilayer substrate 410 (e.g., IPD) with a first portion 450 of a plurality of 3D inductors 430, and a second substrate 420 with a third portion 490 of the plurality of 3D inductors 430, and a fourth portion 495 of the plurality of 3D inductors 430. It should be understood that the first multilayer substrate 410 may be an integrated passive device (IPD) and the second substrate 420 may be a fan-out package.

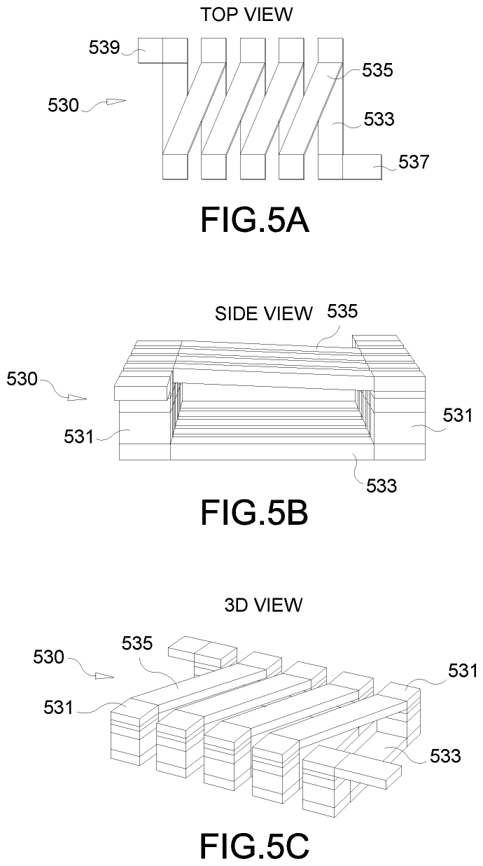

FIGS. 5A-C illustrate an exemplary 3D inductor in accordance with some examples of the disclosure. As shown in FIGS. 5A-C, a 3D inductor 530 (e.g., 3D inductor 130, 3D inductor 230, 3D inductor 330, 3D inductor 430) may include multiple portions such as two rows of vertical posts 531, bottom horizontal layers 533, upper horizontal layers 535, an output 537, and an input 539. As discussed above, an RDL layer (e.g., fourth portion) may form part of the bottom horizontal layers 533, copper pillars, columns, or studs may form part of the vertical posts 531 (e.g., third portion), part of the second substrate may form part of the vertical posts 531 (e.g., second portion), and a first plurality of metal layers in the first multilayer substrate closest to the second substrate may form part of the upper horizontal layers 535 (e.g., a first portion).

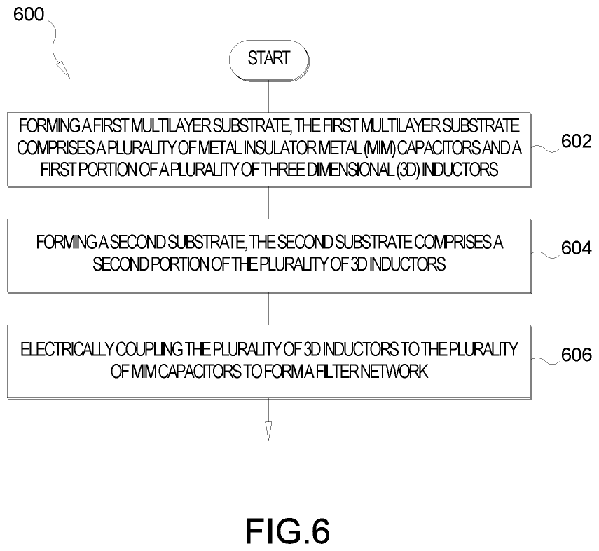

FIG. 6 illustrates an exemplary partial method for manufacturing a filter package in accordance with some examples of the disclosure. As shown in FIG. 6, the partial method 600 may begin in block 602 with forming a first multilayer substrate, the first multilayer substrate comprises a plurality of metal insulator metal (MIM) capacitors and a first portion of a plurality of three dimensional (3D) inductors. The partial method 600 may continue in block 604 with forming a second substrate, the second substrate comprises a second portion of the plurality of 3D inductors. The partial method 600 may conclude in block 606 with electrically coupling the plurality of 3D inductors to the plurality of MIM capacitors to form a filter network. Additionally, the partial method 600 may also include wherein: the first multilayer substrate further comprises a planar inductor; the method further comprises electrically coupling the first multilayer substrate and the second substrate via a plurality of copper pillars in the second substrate and wherein the plurality of copper pillars form a third portion of the plurality of 3D inductors; a redistribution layer in the second substrate forms a fourth portion of the plurality of 3D inductors; the first portion of the plurality of 3D inductors comprises a first plurality of metal layers of the first multilayer substrate closest to the second substrate and the plurality of MIM capacitors comprises a second plurality of metal layers further away from the second substrate than the first plurality of metal layers; the first multilayer substrate further comprises a plurality of planar inductors; the plurality of MIM capacitors are above the first portion of the plurality of 3D inductors opposite the second substrate; at least one of the plurality of MIM capacitors is vertically above at least one of the plurality of 3D inductors and within a vertical perimeter of the at least one of the plurality of 3D inductors; and/or the filter package is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

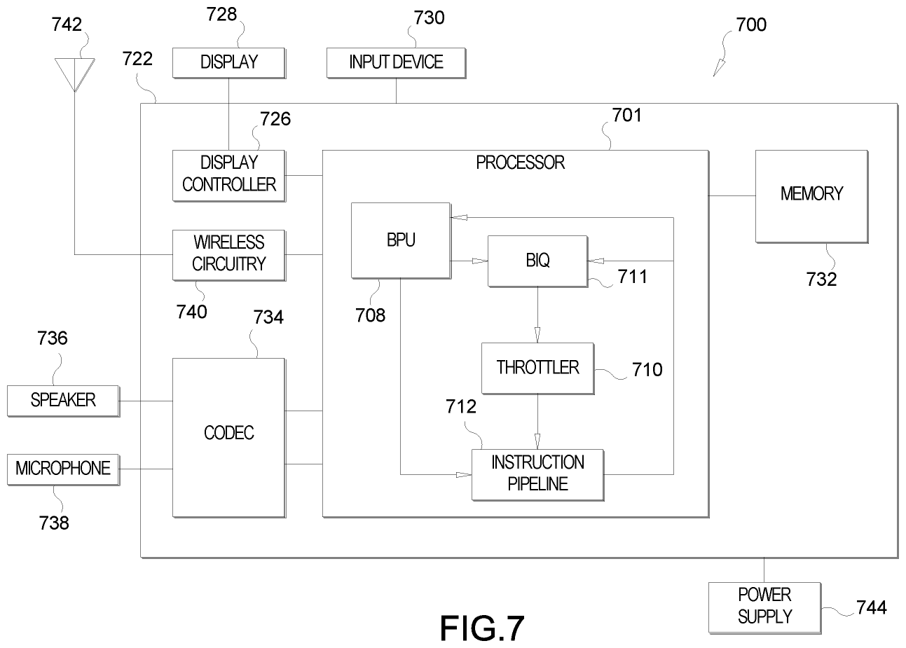

FIG. 7 illustrates an exemplary mobile device in accordance with some examples of the disclosure. Referring now to FIG. 7, a block diagram of a mobile device that is configured according to exemplary aspects is depicted and generally designated 700. In some aspects, mobile device 700 may be configured as a wireless communication device. As shown, mobile device 700 includes processor 701, which may be configured to implement the methods described herein in some aspects. Processor 701 is shown to comprise instruction pipeline 712, buffer processing unit (BPU) 708, branch instruction queue (BIQ) 711, and throttler 710 as is well known in the art. Other well-known details (e.g., counters, entries, confidence fields, weighted sum, comparator, etc.) of these blocks have been omitted from this view of processor 701 for the sake of clarity.

Processor 701 may be communicatively coupled to memory 732 over a link, which may be a die-to-die or chip-to-chip link. Mobile device 700 may also include display 728 and display controller 726, with display controller 726 coupled to processor 701 and to display 728.

In some aspects, FIG. 7 may include coder/decoder (CODEC) 734 (e.g., an audio and/or voice CODEC) coupled to processor 701; speaker 736 and microphone 738 coupled to CODEC 734; and wireless controller 740 (which may include a modem) coupled to wireless antenna 742 and to processor 701.

In a particular aspect, where one or more of the above-mentioned blocks are present, processor 701, display controller 726, memory 732, CODEC 734, and wireless controller 740 can be included in a system-in-package or system-on-chip device 722. Input device 730 (e.g., physical or virtual keyboard), power supply 744 (e.g., battery), display 728, input device 730, speaker 736, microphone 738, wireless antenna 742, and power supply 744 may be external to the system-on-chip device 722 and may be coupled to a component of the system-on-chip device 722, such as an interface or a controller.

It should be noted that although FIG. 7 depicts a mobile device 700, processor 701 and memory 732 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

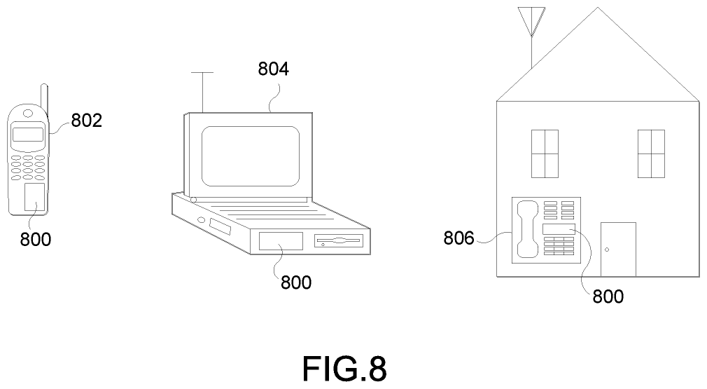

FIG. 8 illustrates various electronic devices that may be integrated with any of the aforementioned integrated device, semiconductor device, integrated circuit, die, interposer, package or package-on-package (PoP) in accordance with some examples of the disclosure. For example, a mobile phone device 802, a laptop computer device 804, and a fixed location terminal device 806 may include an integrated device 800 as described herein. The integrated device 800 may be, for example, any of the integrated circuits, dies, integrated devices, integrated device packages, integrated circuit devices, device packages, integrated circuit (IC) packages, package-on-package devices described herein. The devices 802, 804, 806 illustrated in FIG. 8 are merely exemplary. Other electronic devices may also feature the integrated device 800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

It will be appreciated that various aspects disclosed herein can be described as functional equivalents to the structures, materials and/or devices described and/or recognized by those skilled in the art. It should furthermore be noted that methods, systems, and apparatus disclosed in the description or in the claims can be implemented by a device comprising means for performing the respective actions of this method. For example, in one aspect, a filter package comprises: a first multilayer substrate, the first multilayer substrate comprises a plurality of metal insulator metal (MIM) capacitors and a first portion of means for storing electrical energy (e.g., 3D inductor(s)); and a second substrate, the second substrate comprises a second portion of the means for storing electrical energy wherein the means for storing electrical energy are electrically coupled to the plurality of MIM capacitors to form a filter network. Optionally, the first multilayer substrate further comprises a planar inductor; the first multilayer substrate and the second substrate are electrically coupled via a plurality of copper pillars in the second substrate and the plurality of copper pillars form a third portion of the means for storing electrical energy; a redistribution layer in the second substrate forms a fourth portion of the means for storing electrical energy; the first portion of the means for storing electrical energy comprises a first plurality of metal layers of the first multilayer substrate closest to the second substrate and the plurality of MIM capacitors comprises a second plurality of metal layers further away from the second substrate than the first plurality of metal layers; and/or the first multilayer substrate is an integrated passive device and the second substrate is a fan-out package. It will be appreciated that the aforementioned aspects are merely provided as examples and the various aspects claimed are not limited to the specific references and/or illustrations cited as examples.

One or more of the components, processes, features, and/or functions illustrated in FIGS. 1-8 may be rearranged and/or combined into a single component, process, feature or function or incorporated in several components, processes, or functions. Additional elements, components, processes, and/or functions may also be added without departing from the disclosure. It should also be noted that FIGS. 1-8 and its corresponding description in the present disclosure is not limited to dies and/or ICs. In some implementations, FIGS. 1-8 and its corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package on package (PoP) device, and/or an interposer. An active side of a device, such as a die, is the part of the device that contains the active components of the device (e.g., transistors, resistors, capacitors, inductors, etc.), which perform the operation or function of the device. The backside of a device is the side of the device opposite the active side.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5 (both expressly incorporated herein in their entirety).

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described hereby can be configured to perform at least a portion of a method described hereby.

The terminology used herein is for the purpose of describing particular examples and is not intended to be limiting of examples of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, actions, operations, elements, and/or components, but do not preclude the presence or addition of one or more other features, integers, actions, operations, elements, components, and/or groups thereof.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

Further, those of skill in the art will appreciate that the various illustrative logical blocks, modules, circuits, and algorithm actions described in connection with the examples disclosed herein may be implemented as electronic hardware, computer software, or combinations of both. To clearly illustrate this interchangeability of hardware and software, various illustrative components, blocks, modules, circuits, and actions have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Although some aspects have been described in connection with a device, it goes without saying that these aspects also constitute a description of the corresponding method, and so a block or a component of a device should also be understood as a corresponding method action or as a feature of a method action. Analogously thereto, aspects described in connection with or as a method action also constitute a description of a corresponding block or detail or feature of a corresponding device. Some or all of the method actions can be performed by a hardware apparatus (or using a hardware apparatus), such as, for example, a microprocessor, a programmable computer or an electronic circuit. In some examples, some or a plurality of the most important method actions can be performed by such an apparatus.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or a plurality of claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

Furthermore, in some examples, an individual action can be subdivided into a plurality of sub-actions or contain a plurality of sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A filter package comprising:
a first multilayer substrate, the first multilayer substrate comprises a plurality of metal insulator metal (MIM) capacitors and a first portion of a plurality of three dimensional (3D) inductors; and
a second substrate, the second substrate comprises a second portion of the plurality of 3D inductors wherein the plurality of 3D inductors are electrically coupled to the plurality of MIM capacitors to form a filter network.

2. The filter package of claim 1, wherein the first multilayer substrate further comprises a planar inductor.

3. The filter package of claim 1, wherein the first multilayer substrate and the second substrate are electrically coupled via a plurality of copper pillars in the second substrate and the plurality of copper pillars form a third portion of the plurality of 3D inductors.

4. The filter package of claim 1, wherein a redistribution layer in the second substrate forms a fourth portion of the plurality of 3D inductors.

5. The filter package of claim 1, wherein the first portion of the plurality of 3D inductors comprises a first plurality of metal layers of the first multilayer substrate closest to the second substrate and the plurality of MIM capacitors comprises a second plurality of metal layers further away from the second substrate than the first plurality of metal layers.

6. The filter package of claim 1, wherein the first multilayer substrate is an integrated passive device and the second substrate is a fan-out package.

7. The filter package of claim 1, wherein the first multilayer substrate further comprises a plurality of planar inductors.

8. The filter package of claim 1, wherein the plurality of MIM capacitors are above the first portion of the plurality of 3D inductors opposite the second substrate.

9. The filter package of claim 8, wherein at least one of the plurality of MIM capacitors is vertically above at least one of the plurality of 3D inductors and within a vertical perimeter of the at least one of the plurality of 3D inductors.

10. The filter package of claim 1, wherein the filter package is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

11. A filter package comprising:
a first multilayer substrate, the first multilayer substrate comprises a plurality of metal insulator metal (MIM) capacitors and a first portion of means for storing electrical energy; and
a second substrate, the second substrate comprises a second portion of the means for storing electrical energy wherein the means for storing electrical energy are electrically coupled to the plurality of MIM capacitors to form a filter network.

12. The filter package of claim 11, wherein the first multilayer substrate further comprises a planar inductor.

13. The filter package of claim 11, wherein the first multilayer substrate and the second substrate are electrically coupled via a plurality of copper pillars in the second substrate and the plurality of copper pillars form a third portion of the means for storing electrical energy.

14. The filter package of claim 11, wherein a redistribution layer in the second substrate forms a fourth portion of the means for storing electrical energy.

15. The filter package of claim 11, wherein the first portion of the means for storing electrical energy comprises a first plurality of metal layers of the first multilayer substrate closest to the second substrate and the plurality of MIM capacitors comprises a second plurality of metal layers further away from the second substrate than the first plurality of metal layers.

16. The filter package of claim 11, wherein the first multilayer substrate is an integrated passive device and the second substrate is a fan-out package.

17. The filter package of claim 11, wherein the first multilayer substrate further comprises a plurality of planar inductors.

18. The filter package of claim 11, wherein the plurality of MIM capacitors are above the first portion of the means for storing electrical energy opposite the second substrate.

19. The filter package of claim 18, wherein at least one of the plurality of MIM capacitors is vertically above at least one of the means for storing electrical energy and within a vertical perimeter of the at least one of the means for storing electrical energy.

20. The filter package of claim 11, wherein the filter package is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

21. A method for manufacturing a filter package, the method comprising:
forming a first multilayer substrate, the first multilayer substrate comprises a plurality of metal insulator metal (MIM) capacitors and a first portion of a plurality of three dimensional (3D) inductors;
forming a second substrate, the second substrate comprises a second portion of the plurality of 3D inductors; and
electrically coupling the plurality of 3D inductors to the plurality of MIM capacitors to form a filter network.

22. The method of claim 21, wherein the first multilayer substrate further comprises a planar inductor.

23. The method of claim 21, wherein the method further comprises electrically coupling the first multilayer substrate and the second substrate via a plurality of copper pillars in the second substrate and wherein the plurality of copper pillars form a third portion of the plurality of 3D inductors.

24. The method of claim 21, wherein a redistribution layer in the second substrate forms a fourth portion of the plurality of 3D inductors.

25. The method of claim 21, wherein the first portion of the plurality of 3D inductors comprises a first plurality of metal layers of the first multilayer substrate closest to the second substrate and the plurality of MIM capacitors comprises a second plurality of metal layers further away from the second substrate than the first plurality of metal layers.

26. The filter package of claim 21, wherein the first multilayer substrate further comprises a plurality of planar inductors.

27. The filter package of claim 21, wherein the plurality of MIM capacitors are above the first portion of the plurality of 3D inductors opposite the second substrate.

28. The filter package of claim 27, wherein at least one of the plurality of MIM capacitors is vertically above at least one of the plurality of 3D inductors and within a vertical perimeter of the at least one of the plurality of 3D inductors.

29. The method of claim 21, further comprising incorporating the filter package into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.
